(19) United States
(12) Patent Application Publication
(10) Pub. No.: US 2026/0173896 A1
(43) Pub. Date: Jun. 18, 2026

(54) METHOD OF FABRICATING SEMICONDUCTOR PACKAGE

(71) Applicant: Samsung Electronics Co., Ltd., Suwon-si (KR)

(72) Inventors: Jongyong Kim, Suwon-si (KR); Sunjae Kim, Suwon-si (KR)

(21) Appl. No.: 19/282,706

(22) Filed: Jul. 28, 2025

(30) Foreign Application Priority Data
Dec. 17, 2024 (KR) 10-2024-0188867

(51) Int. Cl. H01L 21/48; H01L 23/00; H01L 23/538; H01L 25/16

(52) U.S. Cl. CPC H10W 70/093; H10W 70/611; H10W 90/00; H10W 90/401; H10W 72/072; H10W 72/07232; H10W 90/724

(57) ABSTRACT

The present disclosure relates to a method of fabricating a semiconductor package. An example method includes forming a lower package, forming a first redistribution substrate on the lower package, and mounting a first semiconductor device on the first redistribution substrate, where the forming of the first redistribution substrate includes planarizing an upper surface of the first redistribution substrate by a polishing process.

### CROSS-REFERENCE TO RELATED APPLICATION

This application claims priority under 35 U.S.C. § 119 to Korean Patent Application No. 10-2024-0188867, filed on Dec. 17, 2024, in the Korean Intellectual Property Office, the disclosure of which is incorporated by reference herein in its entirety.

### BACKGROUND

Electronic apparatuses are becoming more compact and lightweight according to the rapid development of the electronics industry and users'demand. As the electronic apparatuses become smaller and lighter, semiconductor packages used therein are also smaller and lighter. In addition, high reliability along with high performance and large capacity are desired for the semiconductor packages. Recently, as the degree of integration of semiconductor devices has increased and the performance of peripheral devices has also increased, semiconductor packages having stacked structures, such as package-on-package (POP) structures like a three-dimensional integrated circuit (3DIC), have become increasingly important. Generally, the semiconductor packages having stacked structures may include redistribution substrates or interposers, and depending on whether or not including the interposers, the semiconductor packages having stacked structures are classified into 3D package structures and 2.5D package structures.

### SUMMARY

The present disclosure relates to a method of fabricating a semiconductor package, by which a bonding defect may be reduced when semiconductor chips or packages are stacked on a redistribution substrate via connection terminals.

Also, the objects of the present disclosure are not limited to the aforementioned object, but other objects not described herein will be clearly understood by those skilled in the art from the following description.

In general, according to some aspects, a method of fabricating a semiconductor package includes forming a lower package, forming a first redistribution substrate on the lower package, and mounting a first semiconductor device on the first redistribution substrate, wherein the forming of the first redistribution substrate includes planarizing an upper surface of the first redistribution substrate by a polishing process.

In general, according to some aspects, a method of fabricating a semiconductor package includes preparing a first semiconductor device, forming a redistribution substrate on the first semiconductor device, and mounting a second semiconductor device on the redistribution substrate, wherein the forming of the redistribution substrate includes planarizing an upper surface of the redistribution substrate by a polishing process.

In general, according to some aspects, a method of fabricating a semiconductor package includes forming a first redistribution substrate on a lower structure and mounting a first semiconductor device on the first redistribution substrate, wherein the lower structure includes one of a second semiconductor device, a lower package, and an interposer, and the forming of the first redistribution substrate includes planarizing an upper surface of the first redistribution substrate by a polishing process.

### BRIEF DESCRIPTION OF THE DRAWINGS

Implementations will be more clearly understood from the following detailed description taken in conjunction with the accompanying drawings.

FIGS. 1A and 1B are respectively a cross-sectional view and an enlarged cross-sectional view of an example of a semiconductor package.

FIG. 2 is a graph showing an example of a gap between bumps with respect to bonding force depending on presence or absence of a stepped portion on an upper surface of a redistribution substrate.

FIGS. 3A, 3B, and 3C are example cross-sectional views showing in more detail the structure of a second semiconductor device in the semiconductor package of FIG. 1A.

FIG. 4 is a cross-sectional view of an example of a semiconductor package.

FIGS. 5 and 6 are example cross-sectional views of semiconductor packages.

FIGS. 7A, 7B, 7C, 7D, 7E, and 7F are cross-sectional views schematically illustrating an example of a process of fabricating a semiconductor package.

FIGS. 8A, 8B, 8C, 8D, 8E, 8F, and 8G are cross-sectional views showing in more detail an example of a process of forming a second redistribution substrate of FIG. 7E.

FIGS. 9A, 9B, 9C, and 9D are cross-sectional views schematically illustrating an example of a process of fabricating a semiconductor package.

FIGS. 10A, 10B, 10C, and 10D are cross-sectional views schematically illustrating an example of a process of fabricating a semiconductor package.

### DETAILED DESCRIPTION

Hereinafter, implementations are described in detail with reference to the accompanying drawings. The same reference numerals are given to the same elements in the drawings, and repeated descriptions thereof are omitted.

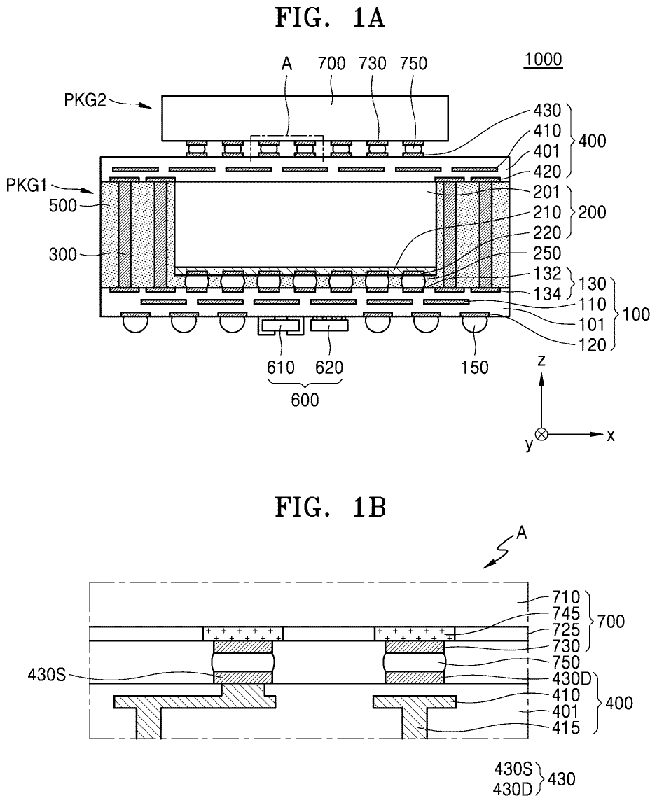

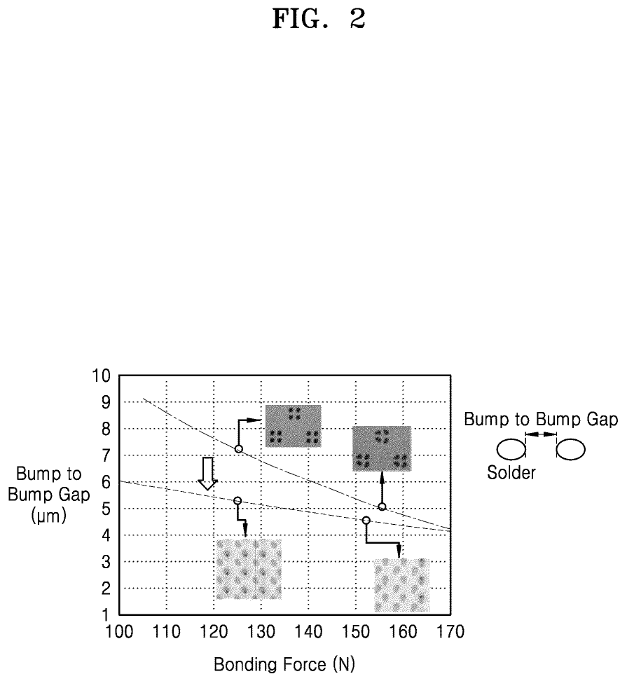

FIGS. 1A and 1B are respectively a cross-sectional view and an enlarged cross-sectional view of an example of a semiconductor package 1000, and FIG. 1B is an enlarged view of region A of FIG. 1A. FIG. 2 is a graph showing an example of a gap between bumps with respect to bonding force depending on presence or absence of a stepped portion on an upper surface of a redistribution substrate.

Referring to FIGS. 1A and 2, the semiconductor package 1000 may include a first redistribution substrate 100, a first semiconductor device 200, a through-post 300, a second redistribution substrate 400, a sealing material 500, a passive device 600, and a second semiconductor device 700.

The first redistribution substrate 100 may be disposed below the first semiconductor device 200 and may function to redistribute a chip pad 220 of the first semiconductor device 200 to an outer region of the first semiconductor device 200. The first redistribution substrate 100 may include a first substrate body 101, a first redistribution line 110, a lower substrate pad 120, and an upper substrate pad 130.

The first substrate body 101 may include polymer. For example, the first substrate body 101 may include photo imageable dielectric (PID) resin and further include inorganic filler. However, the material of the first substrate body 101 is not limited to the materials described above. For example, the first substrate body 101 may include polymide isoindro quirazorindione (PIQ), polyimide (PI), or polybenzoxazole (PBO).

The first substrate body 101 may have a multi-layer structure according to a multi-layer structure of the first redistribution line 110. However, for convenience of illustration, FIG. 1A shows the first substrate body 101 as a single-layer structure. Also, when the first substrate body 101 has a multi-layer structure, all layers may include the same material. However, in some implementations, at least one layer may have different materials or different properties than the other layers. For example, the lowermost layer of the first substrate body 101 may act as a protective layer, protecting the first redistribution line 110 and inner layers of the first substrate body 101 from chemical and physical damage.

The first redistribution line 110 may be arranged in a multi-layer structure inside the first substrate body 101. First redistribution lines 110 adjacent to each other in a z direction may be connected to each other via a vertical via. The first redistribution line 110 and the vertical via may include, for example, copper (Cu). However, the materials of the first redistribution line 110 and the vertical via are not limited to Cu.

The lower substrate pad 120 may be disposed on the lower surface of the first substrate body 101. Also, the lower substrate pad 120 may be connected to the first redistribution line 110 that is lowermost among the first redistribution lines 110. An external connection terminal 150 may be disposed on the lower substrate pad 120. In some implementations, the lower substrate pad 120 may be provided as part of the first redistribution line 110.

External connection terminals 150 may be disposed on a below-chip region corresponding to the lower surface of the first semiconductor device 200 and on an outside-chip region extending from the below-chip region to the outside. In other words, the first redistribution substrate 100 may rearrange the chip pad 220 of the first semiconductor device 200 to a region wider than the lower surface of the first semiconductor device 200 via the first redistribution line 110. As described above, a package structure, in which the external connection terminals 150 are arranged widely beyond the below-chip region to the outside-chip region of the first semiconductor device 200, is referred to as a fan-out (FO) package structure. On the other hand, compared to the FO package structure, a package structure, in which the external connection terminals 150 are arranged only in the below-chip region corresponding to the lower surface of the first semiconductor device 200, is referred to as a fan-in (FI) package structure.

The external connection terminal 150 may connect the semiconductor package 1000 to a package substrate of an external system or to a main board of an electronic device, such as a mobile device. The external connection terminal 150 may include a conductive material, for example, at least one of solder, tin (Sn), silver (Ag), copper (Cu), and aluminum (Al). However, the material of the external connection terminal 150 is not limited to the materials described above.

The upper substrate pad 130 may be disposed on the upper surface of the first substrate body 101. Also, the upper substrate pad 130 may be connected to the first redistribution line 110 that is uppermost among the first redistribution lines 110. Upper substrate pads 130 may include a first upper substrate pad 132 and a second upper substrate pad 134. A first connection terminal 250 of the first semiconductor device 200 may be connected to the first upper substrate pad 132. The through-post 300 may be connected onto the second upper substrate pad 134. The first upper substrate pad 132 may be smaller in size than the second upper substrate pad 134. Here, the size thereof may represent an area on an x-y plane.

The first semiconductor device 200 may be mounted above the first redistribution substrate 100 via the first connection terminal 250. As illustrated in FIG. 1A, the first semiconductor device 200 may be located in a central region of the first redistribution substrate 100. As illustrated in FIG. 1A, the first semiconductor device 200 may be located in a central region of the first redistribution substrate 100 in an x direction and a y direction. However, the location of the first semiconductor device 200 is not limited thereto. For example, the first semiconductor device 200 may be positioned biased to one side in the x direction and the y direction, on the first redistribution substrate 100.

The first semiconductor device 200 may include a logic chip. The logic chip may include a plurality of logic devices therein. The logic devices may include, for example, AND, NAND, OR, NOR, exclusive OR (XOR), exclusive NOR (XNOR), inverter (INV), adder (ADD), delay (DLY), filter (FIL), multiplexer (MXT/MXIT), OR/AND/INVERTER (OAI), AND/OR (AO), AND/OR/INVERTER (AOI), D flip-flop, reset flip-flop, master-slave flip-flop, latch, counter, or buffer devices. The logic devices may perform various types of signal processing, such as analog signal processing, analog-to-digital (A/D) conversion, and control.

Depending on functions, the first semiconductor device 200 may be referred to as a central processing unit (CPU) chip, a micro-processor unit (MPU) chip, a graphic processing unit (GPU) chip, a neural processing unit (NPU) chip, a system on glass (SOG) chip, an application specific integrated circuit (ASIC) chip, a micro-processor chip, an application processor (AP) chip, or a controller chip. Also, according to the types of the first semiconductor device 200, the semiconductor package 1000 may be distinguished as a server-oriented semiconductor device or a mobile-oriented semiconductor device. However, the first semiconductor device 200 is not limited to the logic chip. For example, in some implementations, the first semiconductor device 200 may include a memory chip.

The first semiconductor device 200 may include a substrate 201, an active layer 210, and a chip pad 220. The substrate 201 may include silicon (Si), for example, single crystalline Si, polycrystalline Si (poly-Si), or amorphous Si. However, the material of the substrate 201 is not limited to Si. For example, in some implementations, the substrate 201 may include a group IV semiconductor such as germanium (Ge), a group IV-IV compound semiconductor such as silicon germanium (SiGe) and silicon carbide (SiC), or a group III-V compound semiconductor such as gallium arsenide (GaAs), indium arsenide (InAs), and indium phosphide (InP).

The substrate 201 may be based on a silicon bulk substrate. Also, the substrate 201 may be based on a silicon on insulator (SOI) substrate or a germanium-on-insulator (GeOI) substrate. The substrate 201 is not limited to a bulk, SOI, or GeOI substrate, and may also be based on an epitaxial wafer, a polished wafer, or a heat-treated (annealed) wafer.

The active layer 210 may be located in a lower portion of the substrate 201. The active layer 210 may include an integrated circuit layer and a wiring layer. The integrated circuit layer may be formed by using an impurity region of the substrate 201. For example, the integrated circuit layer may include transistors that include gate electrodes and impurity regions such as source/drain regions. However, elements in the integrated circuit layer are not limited to the transistor. The wiring layer may be disposed below the integrated circuit layer. The wiring layer may include multi-layer wires, and wires at different layers may be connected to each other through a via.

The chip pad 220 may be disposed on the lower surface of the active layer 210. The chip pad 220 may be connected to the wires of the wiring layer of the active layer 210. The first connection terminal 250 may be disposed on the chip pad 220. Therefore, the first connection terminal 250 may be connected to the wires of the wiring layer of the active layer 210 via the chip pad 220.

The first semiconductor device 200 may be mounted above the first redistribution substrate 100 in a flip-chip structure. Specifically, in the first semiconductor device 200, the lower surface of the active layer 210 may represent an active surface and face the first redistribution substrate 100. Accordingly, the first connection terminal 250 is disposed on the lower surface of the active layer 210, and the first semiconductor device 200 may be mounted above the first redistribution substrate 100 in a flip-chip structure. Also, in the first semiconductor device 200, the upper surface of the substrate 201 may represent a non-active surface, and the upper surface of the substrate 201 may face the second redistribution substrate 400.

As illustrated in FIG. 1A, the upper surface of the first semiconductor device 200 may be in direct contact with the lower surface of the second redistribution substrate 400. In other words, the sealing material 500 may not be provided between the first semiconductor device 200 and the second redistribution substrate 400. However, in some implementations, the sealing material 500 may be provided between the first semiconductor device 200 and the second redistribution substrate 400.

The through-post 300 may be located between the first redistribution substrate 100 and the second redistribution substrate 400. As the sealing material 500 is located between the first redistribution substrate 100 and the second redistribution substrate 400, the through-post 300 may extend through the sealing material 500. The through-post 300 may electrically connect the first redistribution substrate 100 to the second redistribution substrate 400. For example, the lower surface of the through-post 300 may be connected to the upper substrate pad 130 of the first redistribution substrate 100, and the upper surface of the through-post 300 may be connected to a lower substrate pad 420 of the second redistribution substrate 400.

The through-post 300 may include Cu. Accordingly, the through-post 300 may be referred to as a Cu post. However, the material of the through-post 300 is not limited to Cu. As described above, the through-post 300 may be disposed on the second upper substrate pad 134. The through-post 300 may be formed by electro-plating.

The second redistribution substrate 400 may be disposed on the first semiconductor device 200, the through-post 300, and the sealing material 500. The second redistribution substrate 400 may have a similar structure to the first redistribution substrate 100. For example, the second redistribution substrate 400 may include a second substrate body 401, a second redistribution line 410, a lower substrate pad 420, and an upper substrate pad 430. The second substrate body 401, the second redistribution line 410, the lower substrate pad 420, and the upper substrate pad 430 are the same as the first substrate body 101, the first redistribution lines 110, the lower substrate pad 120, and the upper substrate pad 130 of the first redistribution substrate 100, respectively, described above.

However, the number of layers of the second redistribution line 410 may be less than that of the first redistribution line 110. Accordingly, the thickness of the second substrate body 401 or the second redistribution substrate 400 may be less than the thickness of the first substrate body 101 or the first redistribution substrate 100. However, in some implementations, the number of layers in the second redistribution line 410 is the same as the number of layers in the first redistribution line 110, and thus, the thickness of the second redistribution substrate 400 may be substantially the same as the thickness of the first redistribution substrate 100.

The second redistribution line 410 of the second redistribution substrate 400 may be connected to the first semiconductor device 200 and the external connection terminal 150 via the through-post 300 and the first redistribution line 110 of the first redistribution substrate 100. Also, when the second substrate body 401 of the second redistribution substrate 400 has a multi-layer structure, at least one layer thereof may have different materials or different characteristics from the other layers. For example, the uppermost layer of the second substrate body 401 may act as a protective layer, protecting the second redistribution line 410 and inner layers of the second substrate body 401 from chemical and physical damage.

Also, the second redistribution substrate 400 may have a structure having the planarized upper surface as shown in FIG. 1B. In more detail, when forming a redistribution substrate, the uppermost redistribution line is formed, and then an insulating layer material, such as PID, is applied thereto to form the uppermost layer of a substrate body. Subsequently, an upper substrate pad is formed on the upper surface of the substrate body by electro-plating. However, due to the presence of a redistribution line directly below, the upper surface of the substrate body may not be flat and have stepped portions. In addition, due to the stepped portions on the upper surface of the substrate body, there may be a height difference between upper substrate pads. The stepped portions on the upper surface of the substrate body may induce non-uniform flow of non-conductive film (NCF) during thermal compression (TC)-NCF process in a subsequent stacking process of a semiconductor device, thereby reducing a bump gap margin and causing a solder short-circuit failure. In addition, the height difference between the upper substrate pads may cause non-wet defects in the upper substrate pads with a relatively low height.

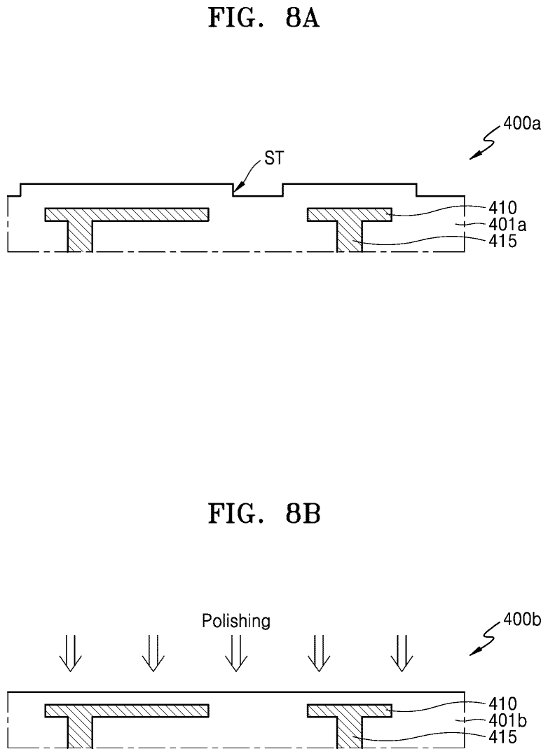

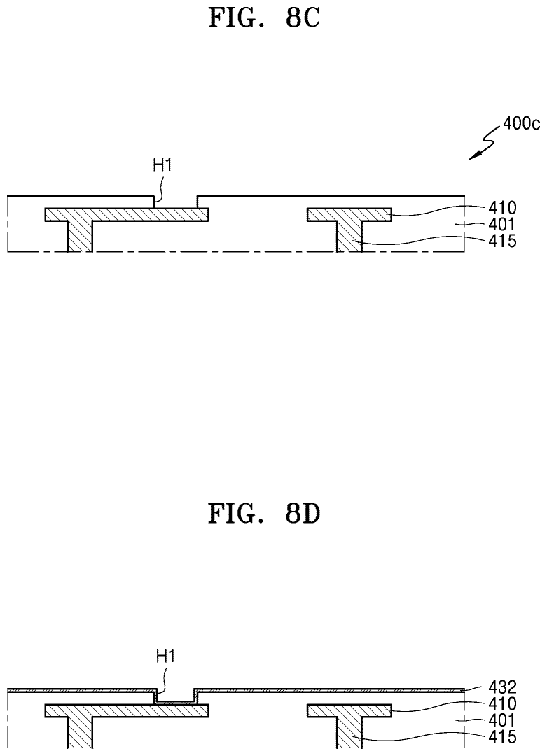

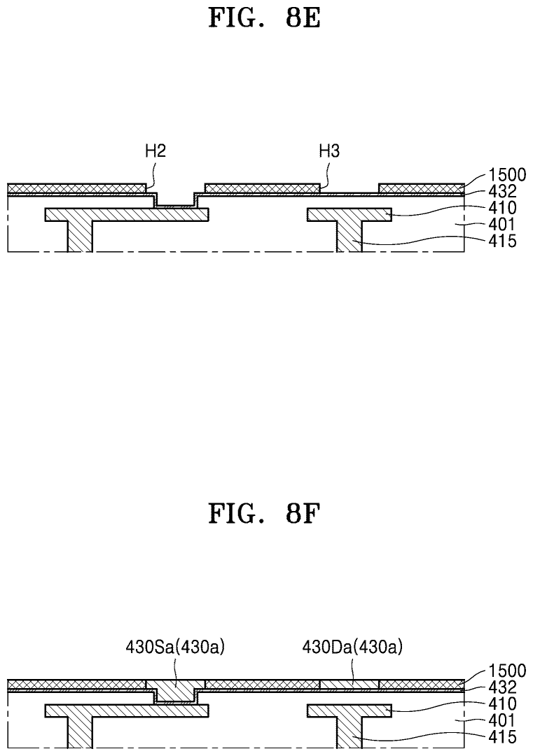

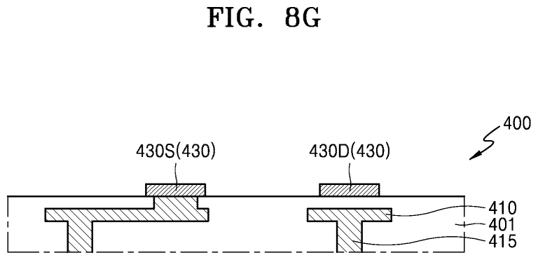

On the other hand, in the semiconductor package 1000, when forming the second redistribution substrate 400, the second redistribution line 410 is formed in the uppermost region, and then a thick insulating layer material, such as PID, is applied thereto. Subsequently, a process of planarizing the surface of the PID by a polishing process may be performed to form the uppermost layer of the second substrate body 401. Accordingly, the upper surface of the second redistribution substrate 400, i.e. the upper surface of the second substrate body 401, may have a planarized structure without stepped portions. In addition, due to the planarized state of the upper surface of the second substrate body 401, the heights of the upper substrate pads 430 may also be uniform. As a result, in the subsequent stacking process of the second semiconductor device 700, the planarized state of the upper surface of the second substrate body 401 may induce the uniform flow of the NCF during the TC-NCF process, thereby increasing the bump gap margin and preventing solder short-circuit failures. In addition, since the upper substrate pads 430 have uniform heights without height differences, non-wet defects caused by height differences in the upper substrate pads 430 may also be reduced. The process of forming the second redistribution substrate 400 is described in more detail in the description with reference to FIGS. 8A to 8G.

The bump gap margin is described in more detail with reference to the graph in FIG. 2. In the graph of FIG. 2, an x-axis represents bonding force, i.e., bonding strength, in units of newtons (N), and a y-axis represents a gap between bumps, i.e., a distance between adjacent bumps in a horizontal direction, as shown on the right side of the graph, in units of micrometers (um). In addition, the height of the bump, i.e., the solder, may be about 12 μm. The alternate long and short dash line in an upper region of the graph shows a case in which there is no stepped portion on the upper surface of the second redistribution substrate 400 as in the semiconductor package 1000, and the dashed line in a lower region of the graph shows a case in which there is a stepped portion on the upper surface of a second redistribution substrate in a semiconductor package according to a comparative example.

As shown in the graph of FIG. 2, it can be seen that if there is a stepped portion on the upper surface of the second redistribution substrate in the semiconductor package according to the comparative example, the gap between bumps is small regardless of the bonding force. This may be due to a non-uniform flow of NCF during the TC-NCF process and a consequent increase in the sweeping of the solder. In scanning acoustic tomography (SAT) images attached below the dashed line, wide and light gray regions show that there is sweeping on the solder.

On the other hand, in the semiconductor package 1000, it can be seen that if there is no stepped portion on the upper surface of the second redistribution substrate 400, the gap between the bumps is relatively large at low bonding force. Therefore, the bump gap margin may be increased by the amount indicated by an arrow at the low bonding force. In the SAT images above the alternate long and short dash lines, the narrow black regions show that there is little or no swiping on the solder.

In the enlarged cross-sectional view in FIG. 1B, the second redistribution line 410 of the second redistribution substrate 400 may be connected to a second redistribution line 410 of another layer via a vertical via 415. Also, the upper substrate pad 430 may include a signal substrate pad 430S and a dummy substrate pad 430D. The signal substrate pad 430S may be connected to the second redistribution line 410 and transmit a signal. In addition, the signal substrate pad 430S may also transmit power and/or ground. On the other hand, the dummy substrate pad 430D may not be connected to the second redistribution line 410. The dummy substrate pad 430D may be arranged for uniform distribution of upper substrate pads 430 and sufficient support for the second semiconductor device 700.

In the enlarged cross-sectional view of FIG. 1B, the second semiconductor device 700 may be provided as a single chip and stacked on the second redistribution substrate 400 via a second connection terminal 750. The second connection terminal 750 may be disposed on a chip pad 730 on the lower surface of the second semiconductor device 700. The chip pad 730 may be connected to an Al pad 745 that is located inside a protective layer 725 on the lower surface of the second semiconductor device 700. The Al pad 745 may be connected to wires in a wiring layer of an active layer 710 of the second semiconductor device 700.

For reference, the second semiconductor device 700 may be formed as a package. In such a case, the second connection terminal 750 may be connected to a substrate pad of the package and connected to substrate wires via the substrate pad. In addition, the second semiconductor device 700 may be formed as a high bandwidth memory (HBM) package. In such a case, the second connection terminal 750 may be connected to a chip pad of a buffer chip and connected to wires in a wiring layer of an active layer of the buffer chip via the Al pad 745.

In addition, in some implementations, the first redistribution substrate 100 may also have a planarized upper surface. For example, when forming the first redistribution substrate 100, the uppermost layer of the first substrate body 101 may be planarized by a polishing process, and thus, the upper surface of the first redistribution substrate 100 may be planarized.

The sealing material 500 may be located between the first redistribution substrate 100 and the second redistribution substrate 400. The sealing material 500 may cover and seal the side surfaces of the first semiconductor device 200 and the through-post 300. In addition, as shown in FIG. 1A, the sealing material 500 may fill a space between the first semiconductor device 200 and the first redistribution substrate 100 and a space between first connection terminals 250 on the lower surface of the first semiconductor device 200. However, in some implementations, an underfill may fill a space between the first semiconductor device 200 and the first redistribution substrate 100, and the sealing material 500 may cover the side surface of the underfill.

The sealing material 500 may include, for example, thermosetting resin, such as epoxy resin, or thermoplastic resin, such as polyimide. In addition, the sealing material 500 may include resin, for example, ABF, FR-4, BT resin, or the like, which is formed by adding a reinforcing material, such as an inorganic filler, to thermosetting resin or thermoplastic resin. Also, the sealing material 500 may include a molding material, such as an epoxy mold compound (EMC), or a photosensitive material, such as a photo imageable encapsulant (PIE). However, the material of the sealing material 500 is not limited to the materials described above.

The passive device 600 may be disposed on the lower surface of the first redistribution substrate 100. In some implementations, the passive device 600 may be located on the upper surface or inside of the first redistribution substrate 100. In addition, the passive device 600 may be located on the lower surface, upper surface, or inside of the second redistribution substrate 400. The passive device 600 may include two-terminal devices, such as resistors, inductors, and capacitors. In the semiconductor package 1000, the passive device 600 may include a multi-layer ceramic capacitor (MLCC) 610 and a silicon (Si)-capacitor 620.

The second semiconductor device 700 may be mounted above the second redistribution substrate 400 via the second connection terminal 750. The second semiconductor device 700 may include a single chip or a package with a plurality of chips. For example, when the second semiconductor device 700 includes a single chip, the second semiconductor device 700 may include one memory chip. When the second semiconductor device 700 includes a package, the second semiconductor device 700 may include, for example, a plurality of memory chips.

When the second semiconductor device 700 includes a memory chip, the second semiconductor device 700 may include, for example, a volatile memory device, such as dynamic random-access memory (DRAM) and static random-access memory (SRAM), or a non-volatile memory device, such as flash memory, electrically erasable programmable read-only memory (EEPROM), phase-change random-access memory (PRAM), magnetoresistive random-access memory (MRAM), ferroelectric random-access memory (FeRAM), resistive random-access memory (RRAM). In the semiconductor package 1000, the second semiconductor device 700 may include, for example, a DRAM chip. However, the second semiconductor device 700 is not limited to the DRAM chip.

Also, when the second semiconductor device 700 includes a package, the semiconductor package 1000 may correspond to a package-on-package (POP) structure. For example, in the semiconductor package 1000, the first redistribution substrate 100, the first semiconductor device 200, the through-post 300, and the second redistribution substrate 400 may constitute a lower package PKG1, and the second semiconductor device 700 in the package structure may constitute an upper package PKG2. Accordingly, the semiconductor package 1000 may have a POP structure in which the upper package PKG2 is stacked on the lower package PKG1.

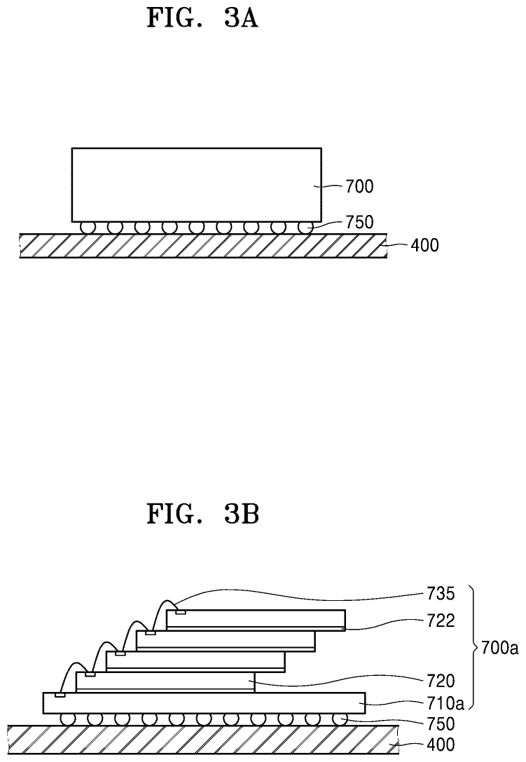

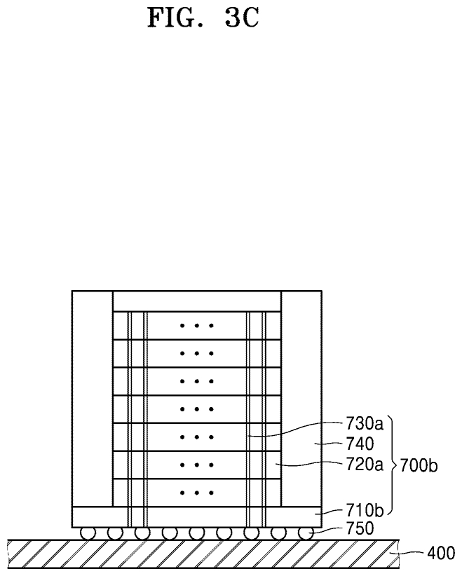

The single chip structure and the package structure of the second semiconductor device 700 are described in more detail in the description with reference to FIGS. 3A to 3C.

In the semiconductor package 1000, the second redistribution substrate 400 may have a structure of which the upper surface is planarized by a polishing process. In addition, the planarized structure of the upper surface of the second redistribution substrate 400 ensures that the heights of the upper substrate pads 430 are maintained uniformly. As a result, in a stacking process of the second semiconductor device 700, the planarized structure of the upper surface of the second redistribution substrate 400 may induce the uniform flow of the NCF during the TC-NCF process, thereby increasing the bump gap margin and preventing solder short-circuit failures. In addition, since the upper substrate pads 430 have uniform heights without height differences, non-wet defects caused by height differences in the upper substrate pads 430 may also be reduced. Consequently, the semiconductor package 1000 may contribute to improving the reliability and increasing the yield of the semiconductor package by reducing solder short-circuit failures and non-wet defects.

FIGS. 3A, 3B, and 3C are example cross-sectional views showing in more detail the structure of the second semiconductor device 700 in the semiconductor package 1000 of FIG. 1A. The descriptions already given with reference to FIGS. 1A to 2 are simplified or omitted.

Referring to FIG. 3A, in the semiconductor package 1000 according to FIG. 1A, the second semiconductor device 700 may include one memory chip. The memory chip may include a volatile memory device, such as DRAM and SRAM, or a non-volatile memory device, such as flash memory. In the semiconductor package 1000, the second semiconductor device 700 may include, for example, a DRAM chip. The second semiconductor device 700 may be mounted above the second redistribution substrate 400 via the second connection terminal 750.

Referring to FIG. 3B, in the semiconductor package 1000 of FIG. 1A, a second semiconductor device 700a may include a semiconductor package having a wire bonding structure. Specifically, the second semiconductor device 700a may include a package substrate 710a and memory chips 720 stacked on the package substrate 710a. A memory chip 720 may be mounted on the package substrate 710a in a wire bonding structure using an adhesive layer 722 and a wire 735. The memory chip 720 of the second semiconductor device 700A may include, for example, a volatile memory device, such as DRAM and SRAM, or a non-volatile memory device, such as flash memory. In the semiconductor package 1000, the memory chip 720 of the second semiconductor device 700a may include, for example, a DRAM chip. In addition, the second semiconductor device 700a may include, on the package substrate 710a, an inner sealing material that seals the memory chips 720 and the wire 735. However, the inner sealing material is omitted in FIG. 3B for convenience of illustration.

In FIG. 3B, four memory chips 720 are stacked on the package substrate 710a, but the number of memory chips 720 is not limited to four. For example, three or less memory chips 720 or five or more memory chips 720 may be stacked on the package substrate 710a. In addition, instead of being limited to a stepped configuration, the memory chip 720 may be stacked on the package substrate 710a in a zigzag configuration or in a combination of the stepped configuration and the zigzag configuration. The second connection terminal 750 may be disposed on the lower surface of the package substrate 710a. Therefore, the second semiconductor device 700a in the package structure may also be mounted above the second redistribution substrate 400 via the second connection terminal 750.

Referring to FIG. 3C, in the semiconductor package 1000 of FIG. 1A, a second semiconductor device 700b may include an HBM package. Specifically, the second semiconductor device 700b may include a base chip 710b, a plurality of core chips 720a stacked on the base chip 710b, and an inner sealing material 740. In addition, the base chip 710b and the core chips 720a may include a through-electrode 730a therein. However, a core chip 720a, which is uppermost among the core chips 720a, may not include the through-electrode 730a.

The base chip 710b may include a logic device. Accordingly, the base chip 710b may be referred to as a logic chip. The base chip 710b may be disposed below the core chips 720a, integrate signals from the core chips 720a, and transmit the integrated signals to the outside. The base chip 710b may also transmit signals and power from the outside to the core chips 720a. Accordingly, the base chip 710b may be referred to as a buffer chip or a control chip.

Each of the core chips 720a may include a memory chip. For example, each of the core chips 720a may include a DRAM chip. Also, the core chip 720a may be stacked on the base chip 710b or the core chip 720a located below, by pad-to-pad bonding, hybrid copper bonding (HCB), bonding using a connection terminal, or bonding using an anisotropic conductive film (ACF). Here, the HCB may represent bonding in which pad-to-pad bonding and insulator-to-insulator bonding are combined. Also, since the pads usually include Cu, the pad-to-pad bonding is also referred to as Cu-to-Cu bonding. Also, the ACF may represent an anisotropic conductive film made to conduct electricity in only one direction and may also represent a conductive film made into a film state by mixing fine conductive particles with an adhesive resin.

In FIG. 3C, eight core chips 720a are stacked on the base chip 710b, but the number of core chips 720a is not limited to eight. For example, seven or less core chips 720a or nine or more core chips 720a may be stacked on the base chip 710b.

The core chips 720a on the base chip 710b may be sealed by the inner sealing material 740. However, the upper surface of the core chip 720a, which is uppermost among the core chips 720a, may not be covered by the inner sealing material 740. However, in other implementations, the upper surface of the core chip 720a, which is uppermost among the core chips 720a, may be covered by the inner sealing material 740. The second connection terminal 750 may be disposed on the lower surface of the base chip 710b. Therefore, the second semiconductor device 700b in the HBM package may also be mounted above the second redistribution substrate 400 via the second connection terminal 750.

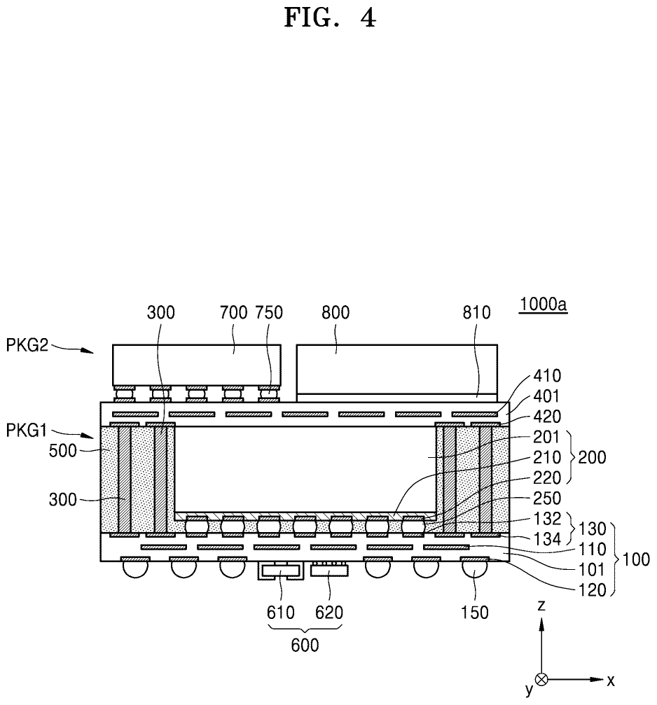

FIG. 4 is a cross-sectional view of an example of a semiconductor package 1000a. The descriptions already given with reference to FIGS. 1A to 3C are simplified or omitted.

Referring to FIG. 4, the semiconductor package 1000a may differ from the semiconductor package 1000 of FIG. 1A in that the semiconductor package 1000a further includes a heat dissipation block 800. Specifically, the semiconductor package 1000a may include the first redistribution substrate 100, the first semiconductor device 200, the through-post 300, the second redistribution substrate 400, the sealing material 500, the passive device 600, the second semiconductor device 700, and the heat dissipation block 800. The first redistribution substrate 100, the first semiconductor device 200, the through-post 300, the second redistribution substrate 400, the sealing material 500, and the passive device 600, and the second semiconductor device 700 are the same as those described in the semiconductor package 1000 of FIG. 1A.

The second semiconductor device 700 may be substantially the same as the second semiconductor device 700 of the semiconductor package 1000 of FIG. 1A. However, the second semiconductor device 700 may be positioned biased to the left side in the x direction, as shown in FIG. 4. For example, the second semiconductor device 700 may be located in a left region, in the x direction, on the second redistribution substrate 400. In some implementations, the first semiconductor device 200 may be positioned biased to the left side in the x direction, and all of through-posts 300 may be arranged on the left side of the first semiconductor device 200 in the x direction. Due to the arrangement described above, a path to the second semiconductor device 700 through the through-post 300 may be optimized.

The heat dissipation block 800 may be adjacent to the second semiconductor device 700 and disposed on the second redistribution substrate 400. For example, the heat dissipation block 800 may be located on the right side, in the x direction, on the second redistribution substrate 400. The heat dissipation block 800 may efficiently dissipate heat generated from the first semiconductor device 200.

The heat dissipation block 800 may be disposed above the second redistribution substrate 400 via an adhesive layer 810. The adhesive layer 810 may bond and fix the heat dissipation block 800 to the second redistribution substrate 400. The adhesive layer 810 may include a material having high thermal conductivity to efficiently transfer heat from the first semiconductor device 200 to the heat dissipation block 800. For example, the adhesive layer 810 may include a thermal interface material (TIM), thermally conductive resin, thermally conductive polymer, silicon oxide such as SiO₂, or silicon nitride such as SiCN. Here, the TIM may include a material having high thermal conductivity, that is, a material having low thermal resistance, such as grease, tape, an elastomer filling pad, and a phase change material.

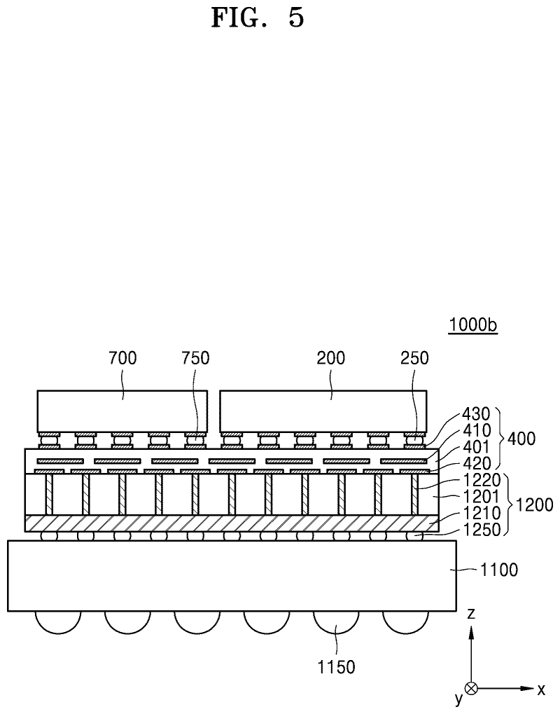

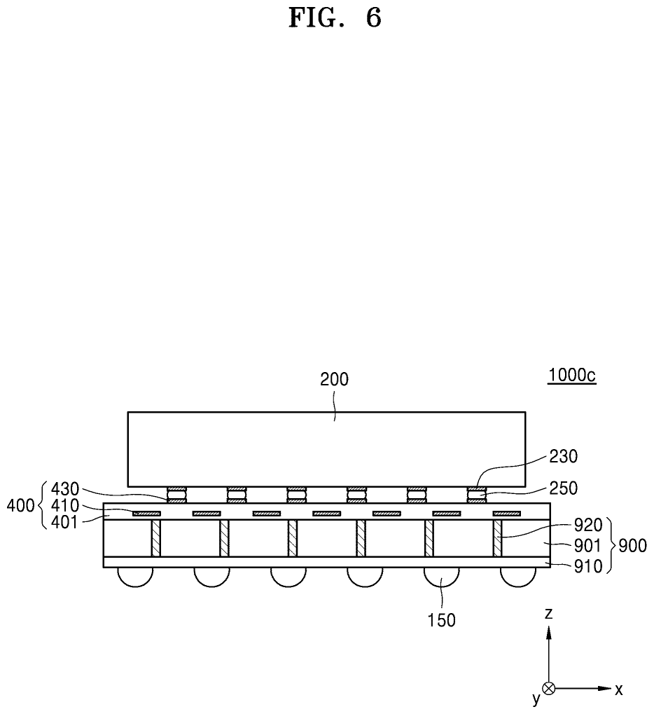

FIGS. 5 and 6 are example cross-sectional views of semiconductor packages 1000b and 1000c, respectively. The descriptions already given with reference to FIGS. 1A to 4 are simplified or omitted.

Referring to FIG. 5, the semiconductor package 1000b may include the first semiconductor device 200, a redistribution substrate 400, the second semiconductor device 700, a package substrate 1100, and an interposer 1200.

The first semiconductor device 200 may correspond to the first semiconductor device 200 in the semiconductor package 1000 of FIG. 1A. Accordingly, the first semiconductor device 200 may include, for example, a logic chip. The first semiconductor device 200 may be mounted above the redistribution substrate 400 via the first connection terminal 250. Also, the redistribution substrate 400 may correspond to the second redistribution substrate 400 in the semiconductor package 1000 of FIG. 1A. Accordingly, the upper surface of the redistribution substrate 400 may have a planarized structure. Therefore, the first semiconductor device 200 and the second semiconductor device 700 may be stably coupled to the redistribution substrate 400 without any solder short-circuit failures or non-wet defects.

Also, the second semiconductor device 700 may correspond to the second semiconductor device 700 in the semiconductor package 1000 of FIG. 1A. Accordingly, the second semiconductor device 700 may include, for example, a memory chip. Also, the second semiconductor device 700 may include a single chip or a package with a plurality of chips. The second semiconductor device 700 may be mounted above the redistribution substrate 400 via the second connection terminal 750.

The package substrate 1100 may include a support substrate, and the interposer 1200 may be stacked on the package substrate 1100. The package substrate 1100 may include at least one layer of wiring lines therein. When the wiring lines include multi layers, the wiring lines at different layers may be connected to each other through a via. The package substrate 1100 may be formed on the basis of, for example, a ceramic substrate, a printed circuit board (PCB), an organic substrate, an interposer substrate, etc. A first external connection terminal 1150 may be disposed on the lower surface of the package substrate 1100. The semiconductor package 1000b may be mounted above an external system board or a main board via the first external connection terminal 1150.

The interposer 1200 may be mounted above the package substrate 1100 via a second external connection terminal 1250. The first and second semiconductor devices 200 and 700 (hereinafter, simply referred to as the semiconductor devices 200 and 700) may be mounted above the package substrate 1100 via the interposer 1200. The interposer 1200 may connect the semiconductor devices 200 and 700 to each other. In addition, the interposer 1200 may connect the semiconductor devices 200 and 700 to the package substrate 1100. In the semiconductor package 1000b, the interposer 1200 may be used to convert electrical signals or to transmit electrical signals between the semiconductor devices 200 and 700. Accordingly, the interposer 1200 may not include active devices. However, in some implementations, the interposer 1200 may include devices for controlling signal transmission. Also, although not illustrated, an underfill may fill a space between the interposer 1200 and the package substrate 1100 and a space between second external connection terminals 1250. In some implementations, the underfill may be replaced with an adhesive layer or an adhesive film.

The interposer 1200 may include an interposer body layer 1201, an interposer wiring layer 1210, and a through-electrode 1220. The interposer body layer 1201 may include, for example, Si. Accordingly, the interposer 1200 may be referred to as a Si-interposer. However, the interposer 1200 is not limited to the Si-interposer.

The interposer wiring layer 1210 may be disposed below the interposer body layer 1201. The interposer wiring layer 1210 may be connected to the through-electrode 1220 in an upper region and to the second external connection terminal 1250 in a lower region. The second external connection terminal 1250 may be disposed on the lower surface of the interposer 1200, that is, on the lower surface of the interposer wiring layer 1210. In some implementations, the interposer wiring layer 1210 may be disposed above the interposer body layer 1201. In addition, interposer wiring layers 1210 may be disposed above and below the interposer body layer 1201.

The interposer wiring layer 1210 may include an interlayer insulating layer and wires. The interlayer insulating layer may have a multi-layer structure according to the multi-layer structure of the wires. All layers in the interlayer insulating layer may include the same material, or at least one layer may include a different material. The wires may be arranged in a multi-layer structure inside the interlayer insulating layer. Wires at different layers may be connected to each other through a via. The wires and the via may include, for example, Cu. However, the materials of the wires and the via are not limited to Cu.

The through-electrode 1220 may extend in the vertical direction, i.e., in the z direction, through the interposer body layer 1201. Since the interposer body layer 1201 includes Si, the through-electrode 1220 may correspond to a through-silicon via (TSV). The through-electrode 1220 may be connected to wires in the interposer wiring layer 1210 in a lower region and may be connected to the second external connection terminal 1250 via the wires. In addition, the through-electrode 1220 may be connected to the lower substrate pad 420 of the redistribution substrate 400 in an upper region.

As shown in FIG. 6, the semiconductor package 1000c may include the first semiconductor device 200, the redistribution substrate 400, and a third semiconductor device 900.

The first semiconductor device 200 may correspond to the first semiconductor device 200 in the semiconductor package 1000 of FIG. 1A. Accordingly, the first semiconductor device 200 may include, for example, a logic chip. The first semiconductor device 200 may be mounted above the redistribution substrate 400 via the first connection terminal 250. Also, the redistribution substrate 400 may correspond to the second redistribution substrate 400 in the semiconductor package 1000 of FIG. 1A. Accordingly, the upper surface of the redistribution substrate 400 may have a planarized structure. Therefore, the first semiconductor device 200 may be stably coupled to the redistribution substrate 400 without any solder short-circuit failures or non-wet defects.

The third semiconductor device 900 may include a logic chip. However, the third semiconductor device 900 is not limited to the logic chip. For example, in some implementations, the third semiconductor device 900 may include a memory chip. When the third semiconductor device 900 includes a logic chip, the third semiconductor device 900 may include a plurality of logic devices.

The third semiconductor device 900 may include, for example, a modem chip that supports communication of the first semiconductor device 200. However, the type of the third semiconductor device 900 is not limited to the modem chip. For example, the third semiconductor device 900 may include other types of integrated devices for performing individual computations or supporting the operation of the first semiconductor device 200. In some implementations, the third semiconductor device 900 may include a multi-channel input/output (I/O) interface for exchanging memory signals with memory devices. In addition, the third semiconductor device 900 may include an SRAM for temporarily storing data.

As shown in FIG. 6, the third semiconductor device 900 may include a substrate 901, an active layer 910, and a through-electrode 920. The substrate 901 and the active layer 910 are the same as the substrate 201 and the active layer 210 of the first semiconductor device 200 in the semiconductor package 1000, respectively, described above with reference to FIG. 1A.

The through-electrode 920 may extend in the vertical direction, i.e., the z direction, through the substrate 901. The lower surface of the through-electrode 920 may be connected to wiring lines of a wiring layer of the active layer 910, and the upper surface of the through-electrode 920 may be connected to a redistribution line 410 of the redistribution substrate 400. Therefore, the third semiconductor device 900 may be connected to the redistribution substrate 400 via the through-electrode 920. In addition, the third semiconductor device 900 may be connected to the first semiconductor device 200 via the through-electrode 920, the redistribution substrate 400, and the first connection terminal 250.

The through-electrode 920 may have a structure that passes through the Si constituting the substrate 901, and may thus correspond to a TSV. For reference, through-electrodes 920 may be classified into a via-first structure, which is formed before formation of an integrated circuit layer of the active layer 910, a via-middle structure, which is formed after formation of the integrated circuit layer and before formation of a wiring layer of the active layer 910, and a via-last structure, which is formed after formation of the wiring layer. In FIG. 6, the through-electrode 920 may, for example, correspond to the via-middle structure. However, the implementation is not limited thereto. In the semiconductor package 1000c, the through-electrode 920 may have the via-first structure or the via-last structure.

In the third semiconductor device 900, the lower surface thereof may be a front-side, which is an active surface, and the upper surface thereof may be a back-side, which is a non-active surface. In other words, the lower surface of the active layer 910 may correspond to the front-side of the third semiconductor device 900, and the upper surface of the substrate 901 may correspond to the back-side of the third semiconductor device 900. A chip pad may be formed on the front-side, which is the active surface, and the external connection terminal 150 may be disposed on the chip pad.

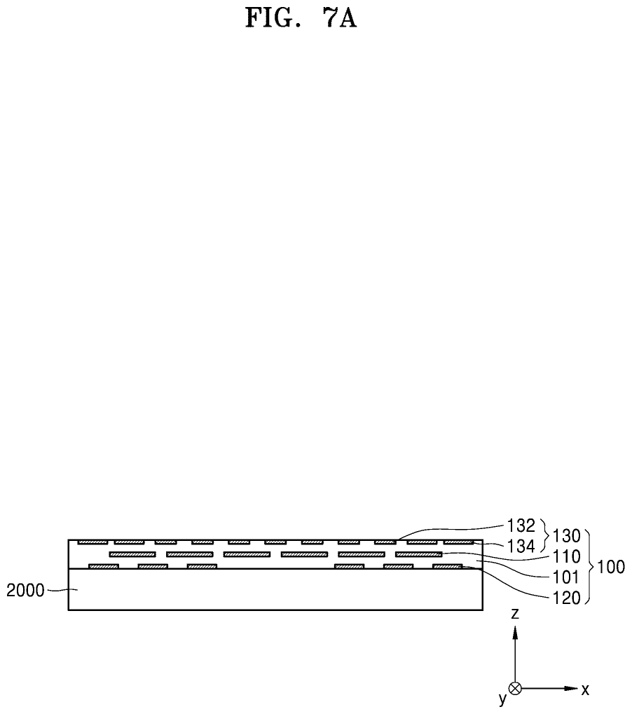

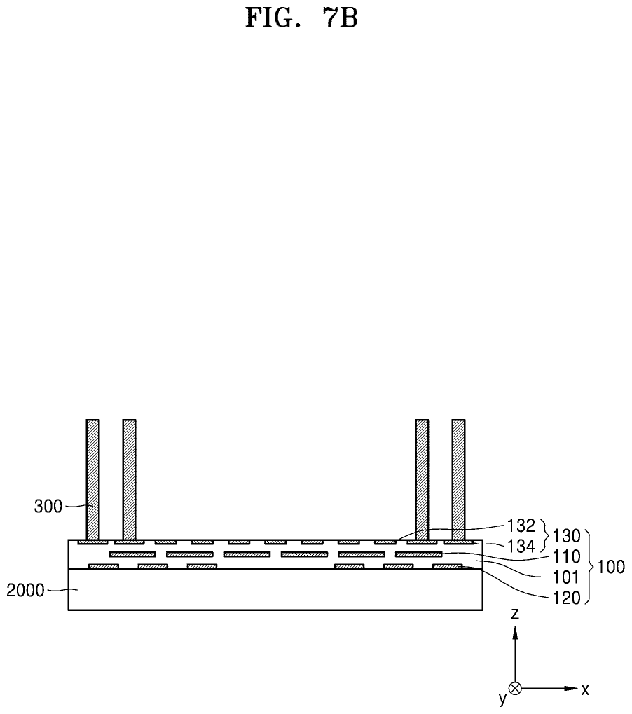

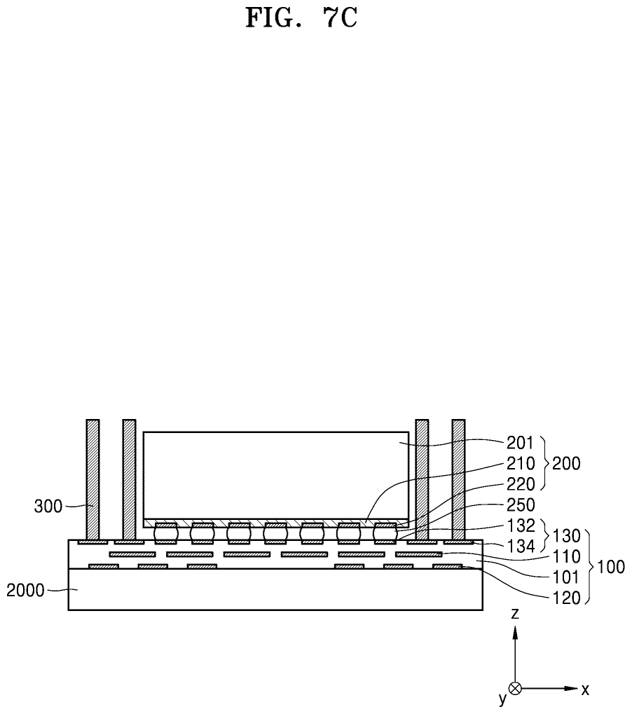

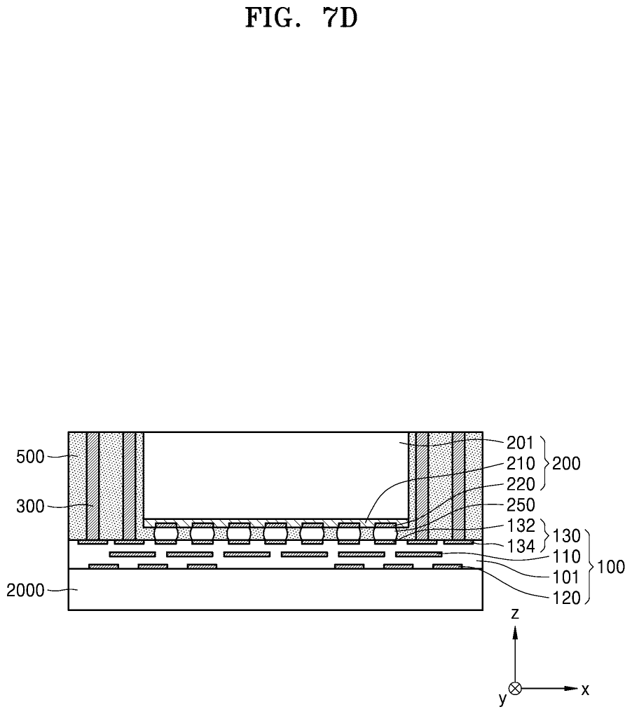

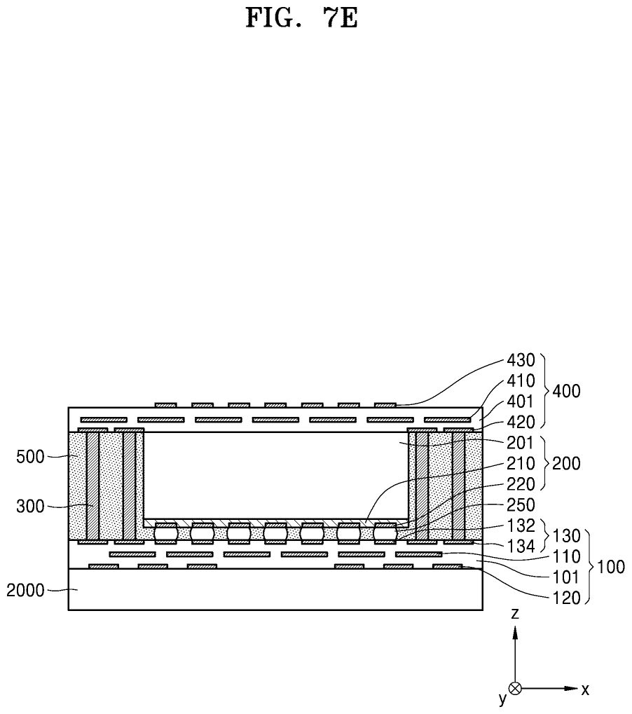

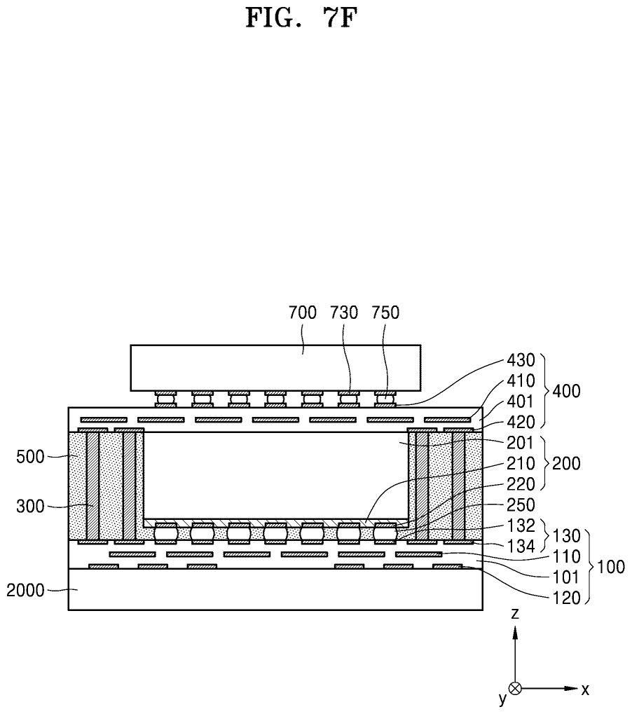

FIGS. 7A, 7B, 7C, 7D, 7E, and 7F are cross-sectional views schematically illustrating an example of a process of fabricating a semiconductor package. A description is given below with reference to FIGS. 1A and 1B together, and descriptions already given with reference to FIGS. 1A to 6 are simplified or omitted.

Referring to FIG. 7A, in the method of fabricating a semiconductor package,, the first redistribution substrate 100 is formed first. The first redistribution substrate 100 may be formed on a carrier substrate 2000. The first redistribution substrate 100 may correspond to, for example, the first redistribution substrate 100 of the semiconductor package 1000 of FIG. 1A. Accordingly, the first redistribution substrate 100 may include the first substrate body 101, the first redistribution lines 110, the lower substrate pad 120, and the upper substrate pad 130. In some implementations, the upper surface of the first redistribution substrate 100 may have a planarized structure. The planarization of the upper surface of the first redistribution substrate 100 may be performed by substantially the same process as the planarization of the upper surface of the second redistribution substrate 400 described below.

Referring to FIG. 7B, after forming the first redistribution substrate 100, the through-post 300 is formed on the second upper substrate pad 134 among the upper substrate pads 130. As shown in FIG. 7B, the first upper substrate pad 132 may be located in a central region, in the x direction, on the first redistribution substrate 100, and the second upper substrate pad 134 may be located in both outer circumferential regions, in the x direction, on the first redistribution substrate 100. Accordingly, the through-posts 300 may be formed in both outer circumferential regions, in the x direction, on the first redistribution substrate 100. In addition, the first semiconductor device 200 may be mounted in the central region, in the x direction, on the first redistribution substrate 100. The through-post 300 may be formed, for example, by electro-plating by using a photo-resist (PR) pattern.

Referring to FIG. 7C, after the formation of the through-post 300, the first semiconductor device 200 is mounted above the first redistribution substrate 100 via the first connection terminal 250. For example, the first semiconductor device 200 may be mounted above the first redistribution substrate 100 by a thermal compression bonding (TCB) process. The first semiconductor device 200 may be located at the center, in the x direction, on the first redistribution substrate 100. The first connection terminal 250 may be coupled to the first upper substrate pad 132 among the upper substrate pads 130. As shown in FIG. 7C, the height of the upper surface of the first semiconductor device 200 may be lower than the height of the upper surface of the through-post 300.

Referring to FIG. 7D, after mounting the first semiconductor device 200, an initial sealing material for covering the first semiconductor device 200 and the through-post 300 is formed. The initial sealing material may cover the side surfaces and upper surfaces of the first semiconductor device 200 and the through-post 300. Also, the initial sealing material may fill a space between the first semiconductor device 200 and the first redistribution substrate 100 and a space between the first connection terminals 250 on the lower surface of the first semiconductor device 200. The material of the initial sealing material is the same as that described in the sealing material 500 of the semiconductor package 1000 in FIG. 1A.

Next, an upper portion of the initial sealing material is removed. The removal of the upper portion of the initial sealing material may be performed, for example, by a grinding process. By removal of the upper portion of the initial sealing material, the upper surface of the first semiconductor device 200 and the upper surface of the through-post 300 may be exposed. Also, after removal of the upper portion of the initial sealing material, the upper surfaces of the first semiconductor device 200, the through-post 300, and the sealing material 500 may be substantially coplanar with each other. The sealing material 500 of the semiconductor package 1000 of FIG. 1A may be formed by removing the upper portion of the initial sealing material.

Referring to FIG. 7E, after the formation of the sealing material 500, the first semiconductor device 200, the through-post 300, and the second redistribution substrate 400 are formed on the sealing material 500. The second redistribution substrate 400 may correspond to, for example, the second redistribution substrate 400 of the semiconductor package 1000 of FIG. 1A. Accordingly, the upper surface of the second redistribution substrate 400 may have a planarized structure. The process of forming the second redistribution substrate 400 is described in more detail in the description with reference to FIGS. 8A to 8G.

Also, the second redistribution line 410 of the second redistribution substrate 400 may have a smaller number of layers than the first redistribution line 110 of the first redistribution substrate 100. Accordingly, the thickness of the second redistribution substrate 400 may be less than the thickness of the first redistribution substrate 100. However, in some implementations, the number of layers of the second redistribution line 410 of the second redistribution substrate 400 may be the same as the number of layers of the first redistribution line 110 of the first redistribution substrate 100. In this case, the thickness of the second redistribution substrate 400 may be substantially the same as the thickness of the first redistribution substrate 100.

Referring to FIG. 7F, the second semiconductor device 700 is mounted above the second redistribution substrate 400 by using the second connection terminal 750. Subsequently, the carrier substrate 2000 is separated from the first redistribution substrate 100 and the structures above the first redistribution substrate 100, and the external connection terminal 150 and the passive device 600 are arranged on the lower surface of the first redistribution substrate 100. As a result, the semiconductor package 1000 of FIG. 1A is fabricated. Also, although not shown, an upper sealing material may be formed on the second redistribution substrate 400 to seal the second semiconductor device 700, and then the process of arranging the external connection terminals 150 and the passive device 600 may be performed.

In addition, the processes described with reference to FIGS. 7A to 7F may be performed in a wafer or a panel substrate. Therefore, after the external connection terminal 150 and the passive device 600 are formed, a plurality of semiconductor packages may be individualized by a sawing process, thereby finally fabricating the semiconductor package 1000 of FIG. 1A.

FIGS. 8A, 8B, 8C, 8D, 8E, 8F, and 8G are cross-sectional views showing in more detail an example of the process of forming the second redistribution substrate 400 of FIG. 7E. A description is given below with reference to FIGS. 1A and 1B together, and descriptions already given with reference to FIGS. 1A to 7F are simplified or omitted.

Referring to FIG. 8A, in the method of fabricating a semiconductor package, the method of forming the second redistribution substrate 400 includes forming an initial second redistribution substrate 400a on the first semiconductor device 200, the through-post 300, and the sealing material 500. The initial second redistribution substrate 400a may include an initial second substrate body 401a, the second redistribution line 410, and the lower substrate pad 420. For example, after the formation of the second redistribution line 410 at the top, a thick insulating layer material, such as PID, may be applied thereto to form the uppermost layer of the initial second substrate body 401a, thereby forming the initial second redistribution substrate 400a.

Also, as shown in FIG. 8A, a stepped portion ST may exist in an upper surface of the initial second substrate body 401a, due to the presence of the second redistribution line 410 below the upper surface of the initial second substrate body 401a. Also, the height of the bottom surface of the stepped portion ST may be made higher than the upper surface of the second redistribution line 410 by forming the thick PID.

Referring to FIG. 8B, the upper surface of the initial second substrate body 401a is planarized by a polishing process. Here, the polishing process may include a grinding process, a lapping process, and a CMP process. For reference, the grinding process may represent the process of mechanically polishing a surface. The lapping process represents the process of making a surface entirely flat by adding abrasives and griding the surface under pressure. The CMP process may represent the process of smoothing a surface by polishing the surface using chemical substances and mechanical friction. Generally, the polishing process may represent the CMP process, and the lapping process may be included in the grinding process.

After the polishing process, the upper surface of an initial second substrate body 401b may have a planarized structure. Through the formation of the initial second substrate body 401b, an initial second redistribution substrate 400b may be formed.

Referring to FIG. 8C, after the formation of the initial second substrate body 401b, a first through-hole H1 is formed in the initial second substrate body 401b. For example, the uppermost layer of the initial second substrate body 401b is patterned by a photolithography process to form the first through-hole H1 in the uppermost layer of the initial second substrate body 401b. Here, the uppermost layer of the initial second substrate body 401b may include the PID. The first through-hole H1 may expose at least partially the second redistribution line 410 that is uppermost among second redistribution lines 410. Through the formation of the first through-hole H1, the second substrate body 401 and an initial second redistribution substrate 400c may be formed.

Referring to FIG. 8D, after the formation of the first through-hole H1, a seed layer 432 is formed on the front-side of the second substrate body 401. For example, the seed layer 432 may cover the upper surface of the second substrate body 401 and the bottom surface and sidewalls of the first through-hole H1. The seed layer 432 may include, for example, titanium (Ti). However, the material of the seed layer 432 is not limited to Ti. For example, the seed layer 432 may include other metal materials, such as Cu, tantalum (Ta), titanium nitride (TiN), and tantalum nitride (TaN).

Referring to FIG. 8E, after the formation of the seed layer 432, a PR pattern 1500 is formed on the seed layer 432. The PR pattern 1500 may include a second through-hole H2 and a third through-hole H3. The second through-hole H2 may open the first through-hole H1. As shown in FIG. 8E, the second through-hole H2 may be a greater width than the first through-hole H1. The first through-hole H1 and the second through-hole H2 may be used to form the signal substrate pad 430S. Also, the third through-hole H3 may partially open the upper surface of the second substrate body 401. The third through-hole H3 may be used to form the dummy substrate pad 430D.

Referring to FIG. 8F, after the formation of the PR pattern 1500, an initial upper substrate pad 430a is formed by a plating process. Specifically, electro-plating is performed by using a portion of the seed layer 432, which is exposed through the first through-hole H1 and the second through-hole H2, and a portion of the seed layer 432, which is exposed through the third through-hole H3, thereby forming a pad metal layer. Subsequently, the pad metal layer around the second through-hole H2 and the third through-hole H3 is partially removed. Accordingly, an initial signal substrate pad 430Sa may be formed inside the first through-hole H1 and the second through-hole H2, and an initial dummy substrate pad 430Da may be formed inside the third through-hole H3.

Referring to FIG. 8G, after the formation of the initial upper substrate pad 430a, the PR pattern 1500 is removed by an ashing/strip process. Subsequently, a portion of the seed layer 432, which has been exposed by the removal of the PR pattern 1500, is removed by an etching process. In the etching process, the seed layer 432 below the initial upper substrate pad 430a may remain. The upper substrate pad 430 may be formed by partially removing the exposed portion of the seed layer 432. Specifically, the signal substrate pad 430S may be formed in the second through-hole H2, and the dummy substrate pad 430D may be formed in the third through-hole H3. Also, the vertical via 415 may be formed in the first through-hole H1 to connect the signal substrate pad 430S to the second redistribution line 410.

Specifically, a portion of the initial signal substrate pad 430Sa, which fills the first through-hole H1, and a remaining portion of the seed layer 432 may form the vertical via 415. In addition, a portion of the initial signal substrate pad 430Sa, which fills the second through-hole H2, and the remaining portion of the seed layer 432 may form the signal substrate pad 430S. Also, a portion of the initial dummy substrate pad 430Da, which fills the third through-hole H3, and the remaining portion of the seed layer 432 may form the dummy substrate pad 430D. In FIG. 8G, the signal substrate pad 430S and dummy substrate pad 430D include the same material as the vertical via 415, but a region of the upper substrate pad 430 is indicated by a different hatching from a region of the vertical via 415 or the second redistribution line 410 in order to distinguish these regions from each other. The second redistribution substrate 400 may be completed by forming the upper substrate pad 430.

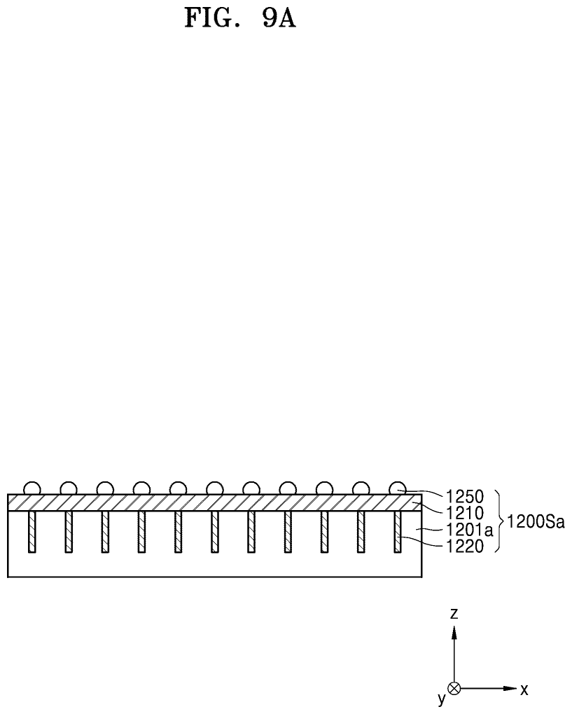

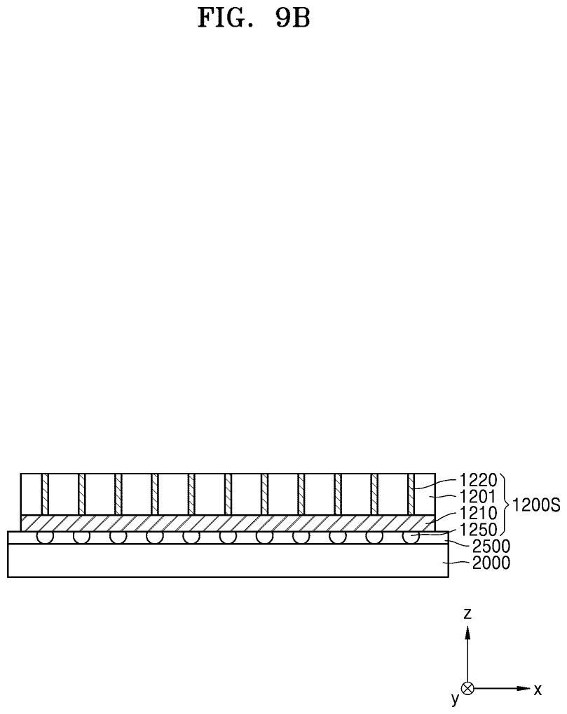

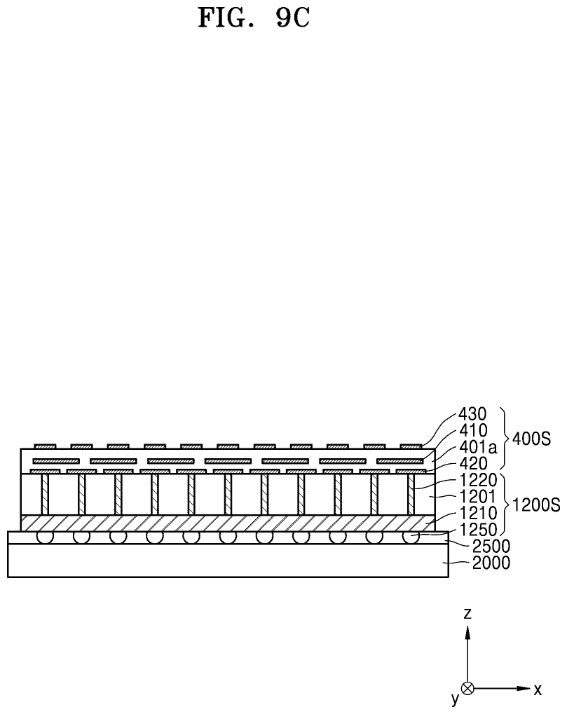

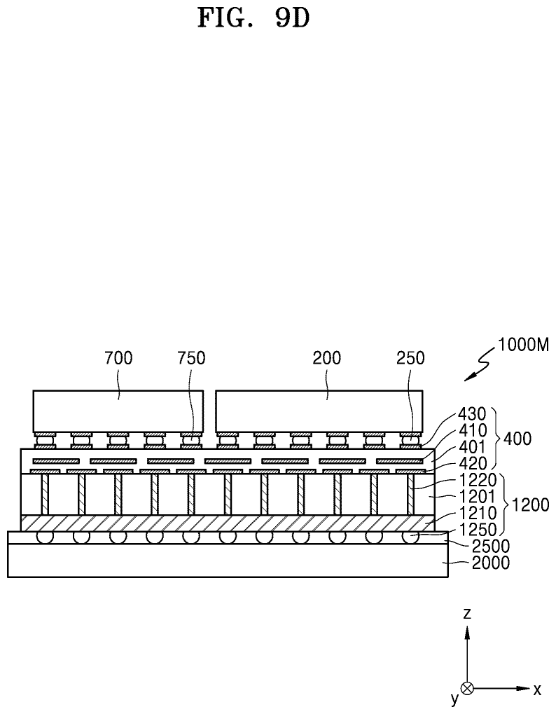

FIGS. 9A, 9B, 9C, and 9D are cross-sectional views schematically illustrating an example of a process of fabricating a semiconductor package. A description is given below with reference to FIG. 5 together, and descriptions already given with reference to FIGS. 1A to 8G are simplified or omitted.

Referring to FIG. 9A, in the method of fabricating a semiconductor package, an initial interposer substrate 1200Sa is formed first. The initial interposer substrate 1200Sa may include an initial interposer body layer 1201a, the interposer wiring layer 1210, and the through-electrode 1220.

The initial interposer substrate 1200Sa may be formed by the following processes. First, the through-electrode 1220 is formed in the initial interposer body layer 1201a. Here, the initial interposer body layer 1201a may have a wafer-level size. Accordingly, the initial interposer substrate 1200Sa may include a plurality of initial interposers. The through-electrode 1220 is the same as the through-electrode 1220 of the interposer 1200 of the semiconductor package 1000b described with reference to FIG. 5. After the formation of the through-electrode 1220, the interposer wiring layer 1210 is formed on the initial interposer body layer 1201a. The interposer wiring layer 1210 may have a wafer-level size to completely cover the initial interposer body layer 1201a. The interposer wiring layer 1210 is the same as the interposer wiring layer 1210 of the interposer 1200 of the semiconductor package 1000b described with reference to FIG. 5. After the formation of the interposer wiring layer 1210, the second external connection terminal 1250 is formed on the interposer wiring layer 1210. Through the formation of the second external connection terminal 1250, the initial interposer substrate 1200Sa may be formed.

Referring to FIG. 9B, after the formation of the second external connection terminal 1250, the initial interposer substrate 1200Sa is turned over and bonded/fixed to the first carrier substrate 2000 via an adhesive layer 2500. Subsequently, the back-side of the initial interposer substrate 1200Sa is partially removed by a grinding process and an etching process, thereby exposing the through-electrode 1220. Through the exposure of the through-electrode 1220, the interposer body layer 1201 may be formed, and an interposer substrate 1200S may also be formed.

Referring to FIG. 9C, after the exposure of the through-electrode 1220, a redistribution substrate layer 400S is formed on the interposer substrate 1200S. The redistribution substrate layer 400S may have a wafer-level size that completely covers the interposer substrate 1200S. That is, the redistribution substrate layer 400S may include a plurality of redistribution substrates 400. The redistribution substrate layer 400S may include a redistribution body layer 401a, the redistribution line 410, the lower substrate pad 420, and the upper substrate pad 430. The redistribution body layer 401a, the redistribution line 410, the lower substrate pad 420, and the upper substrate pad 430 are the same as those described in the second redistribution substrate 400 of the semiconductor package 1000 in FIG. 1A.

Referring to FIG. 9D, after the formation of the redistribution substrate layer 400S, the semiconductor devices 200 and 700 are mounted above the redistribution substrate layer 400S. The semiconductor devices 200 and 700 may include, for example, first semiconductor devices 200 and second semiconductor devices 700. The semiconductor devices 200 and 700 may be mounted above the redistribution substrate layer 400S via the connection terminals 250 and 750. The semiconductor devices 200 and 700 are the same as the semiconductor devices 200 and 700 of the semiconductor package 1000b described with reference to FIG. 5.

Subsequently, the interposer substrate 1200S and the structures above the interposer substrate 1200S are individualized by the sawing process. Through the individualization by the sawing process, an intermediate semiconductor package 1000M may be fabricated. The intermediate semiconductor package 1000M may include the interposer 1200, the redistribution substrate 400, and the semiconductor devices 200 and 700. In addition, although not shown, prior to the individualization by the sawing process, a sealing material may be formed on the redistribution substrate layer 400S to seal the semiconductor devices 200 and 700. Accordingly, the sealing material may also be individualized during the sawing process and thus included in the intermediate semiconductor package 1000M.

After the fabrication of the intermediate semiconductor package 1000M, the intermediate semiconductor package 1000M is mounted above the package substrate 1100 via the second external connection terminal 1250, thereby completing the semiconductor package 1000b. The semiconductor package 1000b may correspond to the semiconductor package 1000b in FIG. 5.

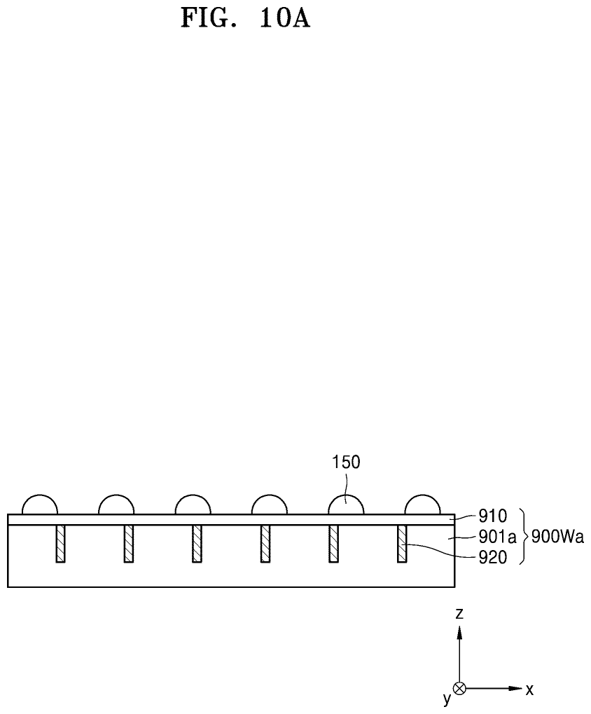

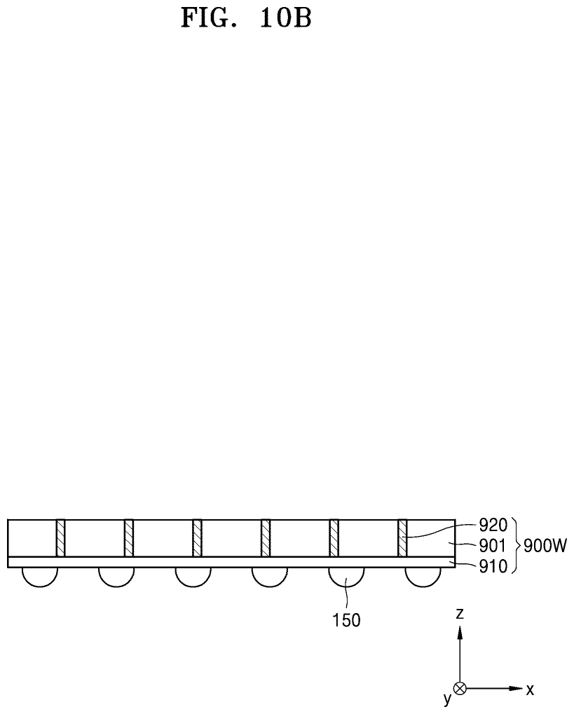

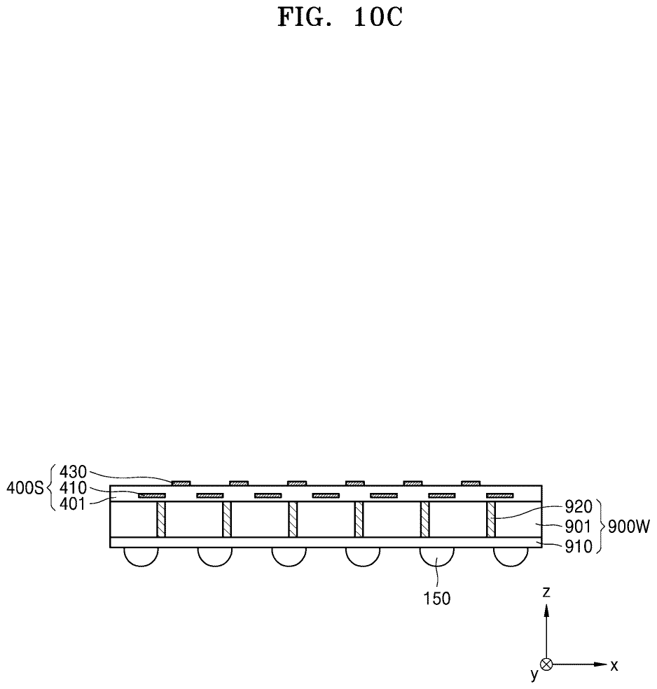

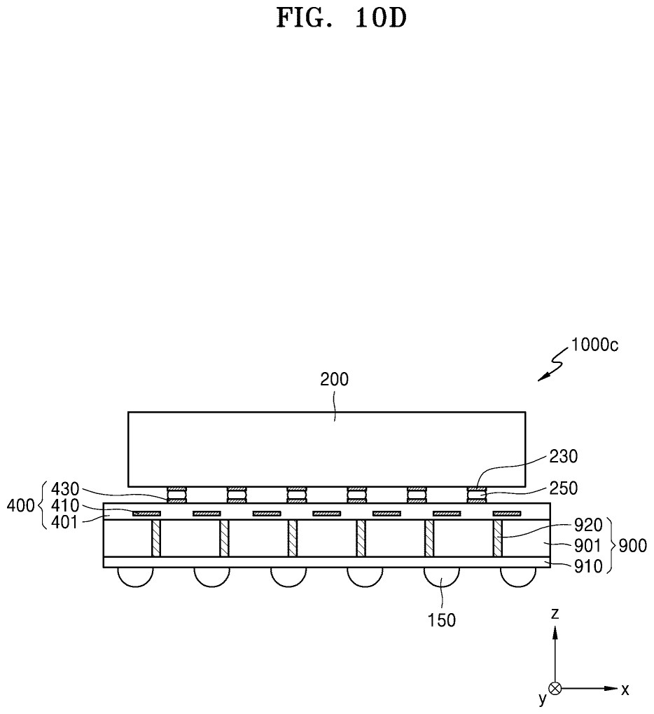

FIGS. 10A, 10B, 10C, and 10D are cross-sectional views schematically illustrating an example of a process of fabricating a semiconductor package. A description is given below with reference to FIG. 6 together, and descriptions already given with reference to FIGS. 1A to 9D are simplified or omitted.

Referring to FIG. 10A, in the method of fabricating a semiconductor package, the external connection terminal 150 is formed first on an initial wafer 900Wa. The initial wafer 900Wa may include a plurality of initial third semiconductor devices. Accordingly, the initial wafer 900Wa may include an initial substrate 901a, the active layer 910, and the through-electrode 920. Here, the initial wafer 900Wa may be in a state prior to a grinding process and thus thicker than a wafer 900W after the grinding process. The lower surface of the through-electrode 920 may not be exposed at the initial wafer 900Wa.

The external connection terminal 150 may be disposed on the chip pad on the active layer 910. When forming the external connection terminal 150, the initial wafer 900Wa may be fixed to the first carrier substrate via an adhesive layer. The external connection terminal 150 is the same as the external connection terminal 150 of the semiconductor package 1000 described with reference to FIG. 1A.

Referring to FIG. 10B, after the formation of the external connection terminal 150, the back-side of the initial wafer 900Wa is removed by a grinding process and an etching process, thereby forming the wafer 900W. The wafer 900W may include a plurality of third semiconductor devices 900. After the grinding process and the etching process, the through-electrode 920 may be exposed. Although not shown, a protective layer may be formed on the back-side of the wafer 900W. The through-electrode 920 may pass through the protective layer and be thus exposed through the protective layer. Here, the grinding process and the etching process may be performed, after separating the initial wafer 900Wa from the first carrier substrate and then coupling the surface of the initial wafer 900Wa, on which external connection terminals 150 are formed, to a second carrier substrate through an adhesive layer.

Referring to FIG. 10C, after the formation of the wafer 900W, the redistribution substrate layer 400S is formed on the back-side of the wafer 900W. The redistribution substrate layer 400S may have a wafer-level size, corresponding to the wafer 900W. Except for the size described above, the redistribution substrate layer 400S is the same as the redistribution substrate 400 of the semiconductor package 1000c described with reference to FIG. 6.

Referring to FIG. 10D, after the formation of the redistribution substrate layer 400S, the first semiconductor device 200 is mounted above the redistribution substrate layer 400S. The first semiconductor device 200 may be located at a position corresponding to the third semiconductor device 900 of the wafer 900W. Accordingly, the plurality of first semiconductor devices 200 may be mounted above the redistribution substrate layer 400S, corresponding to a plurality of third semiconductor devices 900 of the wafer 900W. The first semiconductor device 200 may be mounted above the redistribution substrate layer 400S via the first connection terminal 250. That is, the first connection terminal 250 may connect a chip pad 230 of the first semiconductor device 200 to the upper substrate pad 430 of the redistribution substrate layer 400S.

Subsequently, the wafer 900W, the redistribution substrate layer 400S on the wafer 900W, and the plurality of third semiconductor devices 900 may be separated from the second carrier substrate and individualized by the sawing process in a ring mount apparatus, thereby completing the semiconductor package 1000c. The semiconductor package 1000c may correspond to the semiconductor package 1000c in FIG. 6. In addition, although not shown, prior to the individualization by the sawing process, a sealing material may be formed on the redistribution substrate layer 400S to seal the first semiconductor devices 200. Accordingly, the sealing material may also be individualized during the sawing process and thus included in the semiconductor package 1000c.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been shown and described with reference to implementations thereof, it will be understood that various changes in form and details may be made therein without departing from the spirit and scope of the following claims.

What is claimed is:

1. A method of fabricating a semiconductor package, the method comprising:
forming a lower package;
forming a first redistribution substrate on the lower package; and
mounting a first semiconductor device on the first redistribution substrate,
wherein forming the first redistribution substrate comprises planarizing an upper surface of the first redistribution substrate using a polishing process.

2. The method of claim 1, wherein forming the first redistribution substrate comprises:
forming a first redistribution line on the lower package;
forming a first body layer, the first body layer covering the first redistribution line;
planarizing an upper surface of the first body layer using the polishing process; and
forming, in the first body layer, a first substrate pad, the first substrate pad being connected to the first redistribution line.

3. The method of claim 2, wherein forming the first substrate pad comprises:
patterning the first body layer to form a first open hole, wherein the first open hole partially exposes an upper surface of the first redistribution line;
forming a seed layer on the upper surface of the first body layer and on a bottom and a sidewall of the first open hole;
forming, on the first body layer, a photo-resist (PR) pattern, the PR pattern comprising a second open hole having a greater width than the first open hole; and
forming a first pad metal layer, wherein the first pad metal layer fills the first open hole and the second open hole.

4. The method of claim 3, wherein a portion of the first pad metal layer, which fills the second open hole, forms the first substrate pad, and wherein a portion of the first pad metal layer, which fills the first open hole, forms a vertical via that connects the first substrate pad to the first redistribution line.

5. The method of claim 3, wherein the first body layer comprises a photo-imageable dielectric (PID),
wherein forming the first open hole comprises forming the first open hole using a photolithography process, and
wherein forming the first pad metal layer comprises forming the first pad metal layer using an electro-plating process.

6. The method of claim 3, wherein the PR pattern comprises a third open hole spaced apart from the first open hole, and the third open hole exposes the upper surface of the first body layer,
the method comprising forming a second pad metal layer that fills the third open hole, and
wherein the second pad metal layer defines a dummy substrate pad.

7. The method of claim 3, wherein the first redistribution substrate comprises a plurality of redistribution lines, and
wherein planarizing the upper surface of the first body layer comprises planarizing a portion of the first body layer that covers the first redistribution line, and wherein the first redistribution line is an uppermost redistribution line among the plurality of redistribution lines.

8. The method of claim 1, wherein forming the lower package comprises:
forming a second redistribution substrate on a carrier substrate;
forming a through-post on the second redistribution substrate;
mounting a second semiconductor device on the second redistribution substrate; and
forming, on the second redistribution substrate, a sealing material that seals the second semiconductor device and the through-post,
wherein the first redistribution substrate is formed on the through-post and the sealing material.

9. The method of claim 8, wherein forming the second redistribution substrate comprises:
forming a second redistribution line on the carrier substrate;
forming a second body layer covering the second redistribution line;
planarizing an upper surface of the second body layer using a second polishing process; and
forming a second substrate pad in the second body layer.

10. The method of claim 1, wherein the first semiconductor device comprises a semiconductor chip or the semiconductor package, and
wherein the first semiconductor device is mounted above the first redistribution substrate via a connection terminal.

11. A method of fabricating a semiconductor package, the method comprising:
preparing a first semiconductor device;
forming a redistribution substrate on the first semiconductor device; and
mounting a second semiconductor device on the redistribution substrate,
wherein forming the redistribution substrate comprises planarizing an upper surface of the redistribution substrate using a polishing process.

12. The method of claim 11, wherein forming the redistribution substrate comprises:
forming a redistribution line on the first semiconductor device;
forming a body layer covering the redistribution line;
planarizing an upper surface of the body layer using the polishing process; and
forming, in the body layer, a substrate pad, the substrate pad being connected to the redistribution line.

13. The method of claim 12, wherein forming the substrate pad comprises:
patterning the body layer using a photolithography process to form a first open hole, wherein the first open hole partially exposes an upper surface of the redistribution line;
forming a seed layer on the upper surface of the body layer and on a bottom and a sidewall of the first open hole;
forming, on the body layer, a photo-resist (PR) pattern, the PR pattern comprising a second open hole having a greater width than the first open hole; and
forming, using an electro-plating process, a pad metal layer that fills the first open hole and the second open hole.

14. The method of claim 11, wherein the first semiconductor device comprises a plurality of first semiconductor chips in a wafer,
wherein the redistribution substrate is formed on the plurality of first semiconductor chips in the wafer, and
wherein the second semiconductor device comprises a plurality of second semiconductor chips mounted respectively to the plurality of first semiconductor chips, and
wherein, after mounting the second semiconductor device, the method comprises:
forming, on the redistribution substrate, a sealing material that seals the second semiconductor device; and
individualizing the first semiconductor device, the second semiconductor device, the redistribution substrate, and the sealing material.

15. The method of claim 11, wherein the first semiconductor device comprises a substrate, an active layer below the substrate, and a through-electrode passing through the substrate and connected to the active layer, and
wherein the through-electrode is connected to a redistribution line of the redistribution substrate.

16. The method of claim 11, wherein the second semiconductor device comprises a logic chip, and
wherein the second semiconductor device is mounted above the redistribution substrate via a connection terminal.

17. A method of fabricating a semiconductor package, the method comprising:
forming a first redistribution substrate on a lower structure; and
mounting a first semiconductor device on the first redistribution substrate,
wherein the lower structure comprises a second semiconductor device, a lower package, or an interposer, and
wherein forming the first redistribution substrate comprises planarizing an upper surface of the first redistribution substrate using a polishing process.

18. The method of claim 17, wherein forming the first redistribution substrate comprises:
forming a redistribution line on the lower structure;
forming a body layer covering the redistribution line;
planarizing an upper surface of the body layer using the polishing process;
patterning the body layer to form a first open hole, wherein the first open hole partially exposes an upper surface of the redistribution line;
forming a seed layer on the upper surface of the body layer and on a bottom and a sidewall of the first open hole;
forming, on the body layer, a photo-resist (PR) pattern, wherein the PR pattern comprises a second open hole having a greater width than the first open hole; and
forming a pad metal layer that fills the first open hole and the second open hole.

19. The method of claim 17, wherein the lower structure comprises the lower package, and
wherein prior to forming the first redistribution substrate, the method comprises:
forming a second redistribution substrate on a carrier substrate;
forming a through-post on the second redistribution substrate;
mounting the second semiconductor device on the second redistribution substrate; and
forming, on the second redistribution substrate, a sealing material that seals the second semiconductor device and the through-post,
wherein the first redistribution substrate is formed on the through-post and the sealing material.

20. The method of claim 17, wherein the lower structure comprises the interposer, and
wherein the interposer comprises an interposer substrate, a wiring layer below the interposer substrate, and a through-electrode passing through the interposer substrate and connected to the wiring layer, and
wherein the through-electrode is connected to a redistribution line of the first redistribution substrate.
